(19) United States
(12) Patent Application Publication
(10) Pub. No.: US 2016/0204328 A1
(43) Pub. Date: Jul. 14, 2016

(54) WASTE HEAT POWER GENERATION DEVICE AND GAS APPLIANCE USING THE SAME

(71) Applicant: Qibiao XIE, Zhongshan City (CN)

(72) Inventor: Qibiao XIE, Zhongshan City (CN)

(21) Appl. No.: 14/859,956

(22) Filed: Sep. 21, 2015

(30) Foreign Application Priority Data
Jan. 12, 2015 (CN) 201520022410.6
Feb. 15, 2015 (CN) 201520110763.1
Mar. 5, 2015 (CN) 201520128139.4
Mar. 6, 2015 (CN) 201520148913.8

(51) Int. Cl. H01L 35/30; F23Q 3/00

(52) U.S. Cl. CPC H01L 35/30; F23Q 3/006

(57) ABSTRACT

Disclosed is a waste heat power generation device comprising a temperature difference power generation chip, a heat conduction block tightly attached to the hot end of the temperature difference power generation chip on which a current output end is arranged, and a radiator tightly attached to the cold end of the temperature difference power generation chip, wherein the heat conduction block is used for absorbing and transferring external heat to the hot end. A gas appliance is also disclosed, comprising a combustor, at least one electrical device powered by a chargeable battery, and the waste heat power generation device, wherein the current output end is electrically connected with the battery, and the heat conduction block is used for absorbing and transmitting heat generated from the combustor. The waste heat is converted into electrical energy and stored in the battery.

### CROSS REFERENCE TO RELATED APPLICATIONS

The present application claims priority under 35 USC 119 to Chinese Patent Application No. 201520022410.6, filed Jan. 12, 2015, Chinese Patent Application No. 201520110763.1, filed Feb. 15, 2015, Chinese Patent Application No. 201520128139.4, filed Mar. 5, 2015, and Chinese Patent Application No. 201520148913.8, filed Mar. 6, 2015, the contents of each of which are incorporated herein by reference.

### FIELD OF THE INVENTION

The present invention relates to the field of gas equipment, in particular to a waste heat power generation device and a gas appliance using the same.

### BACKGROUND

An existing gas appliance usually is ignited by adopting an electronic ignition device, wherein the electronic ignition device comprises a battery and a booster circuit, the current of the battery is boosted through the booster circuit and is discharged during ignition, and electric sparks are generated for igniting. The electronic ignition device is long in service life, but the battery needs to be replaced frequently. More and more electrical devices are used in the gas appliance along with the improvement of degree of automation, so that the power consumption of the battery is also increased, and the consumption for battery capacity is also faster and faster. Therefore, the frequency of replacing the battery is further increased, and it's inconvenient for the use of the gas appliance.

### SUMMARY

In order to solve the above-mentioned problems, the present invention aims to provide a waste heat power generation device which is capable of effectively absorbing and utilizing waste heat, and which is energy-saving and environment-friendly. The present invention also aims to provide a gas appliance using the waste heat power generation device.

The technical solution adopted for solving the technical problem of the present invention is as follows:

A waste heat power generation device comprising a temperature difference power generation chip, a heat conduction block tightly attached to the hot end of the temperature difference power generation chip and a radiator tightly attached to the cold end of the temperature difference power generation chip, the heat conduction block is used for absorbing external heat and transferring the external heat to the hot end of the temperature difference power generation chip, and a current output end is arranged on the temperature difference power generation chip.

Preferably, the radiator is a heat dissipating water tank.

Preferably, a water inlet and a water outlet are formed in the heat dissipating water tank.

Preferably, a plurality of radiating fins are arranged on the outer wall of the radiator.

Preferably, a radiating fan is also arranged on the side of the radiator, and airflow generated when the radiating fan works flows through gaps between adjacent radiating fins.

The present invention also discloses a gas appliance, comprising a combustor, at least one electrical device and a chargeable battery for supplying power for the electrical device, and also comprising a waste heat power generation device, wherein the current output end of the temperature difference power generation chip is electrically connected with the battery, and the heat conduction block is used for absorbing and transmitting heat generated when the combustor works.

Preferably, the heat conduction block extends to the place of flames generated when the combustor works.

Preferably, the combustor comprises a hollow cylinder-shaped annular nozzle, the heat conduction block extends into the inner cavity of the annular nozzle, and a plurality of side gas spray ports aligning to the heat conduction block are formed in the inner wall of the annular nozzle.

Preferably, the gas appliance also comprises a shell, the combustor is arranged in the shell, and the radiator is positioned outside the shell.

The present invention is beneficial to the art due to the technical effects that the waste heat of the combustor can be absorbed by utilizing the heat conduction block, the waste heat is converted into electrical energy by the temperature difference power generation chip, and the electrical energy is stored in the battery and is used for the electrical device, so that the service life of the battery can be prolonged, and the battery is prevented from being frequently replaced or even the battery does not need to be replaced; moreover, the radiator is arranged at the cold end of the temperature difference power generation chip, so that the temperature difference between the cold end of the temperature difference power generation chip and the hot end of the temperature difference power generation chip is increased, the power generation efficiency is improved, and the waste heat power generation device is energy-saving and environment-friendly.

### BRIEF DESCRIPTION OF THE DRAWINGS

The present invention is further described in detail with reference to the following drawings and embodiments.

FIG. 1 is a structure diagram of the first embodiment of a waste heat power generation device according to the present invention;

FIG. 2 is a structure diagram of the second embodiment of the waste heat power generation device according to the present invention;

FIG. 3 is a structure diagram of the third embodiment of the waste heat power generation device according to the present invention;

FIG. 4 is a structure diagram of the first embodiment of a gas appliance according to the present invention;

FIG. 5 is a partially enlarged view of the Section 5 in FIG. 4;

FIG. 6 is a structure diagram of the second embodiment of the gas appliance according to the present invention.

### DETAILED DESCRIPTION OF THE EMBODIMENTS

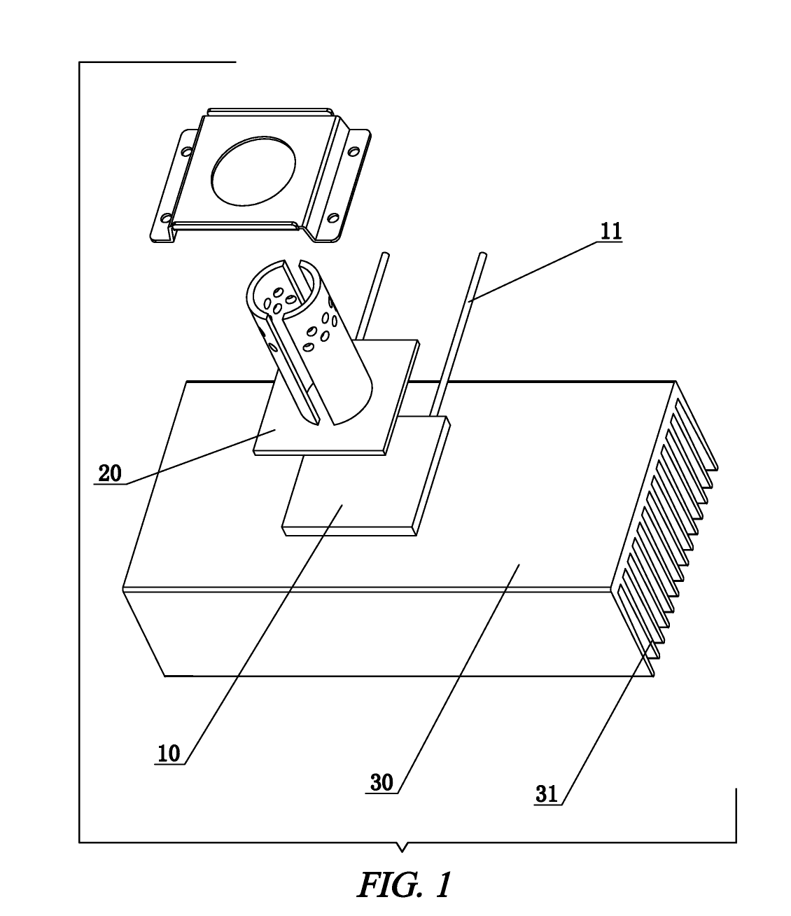

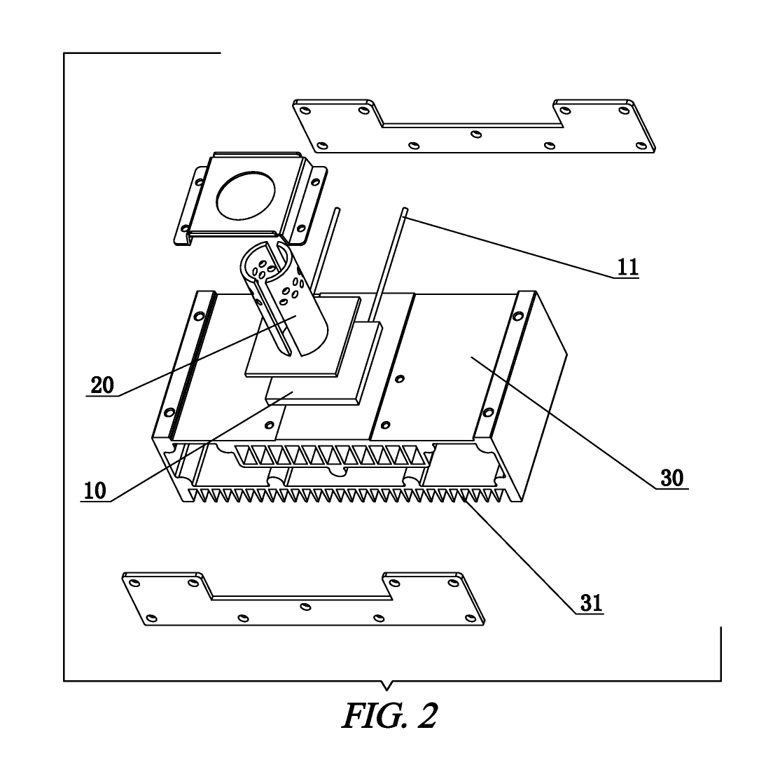

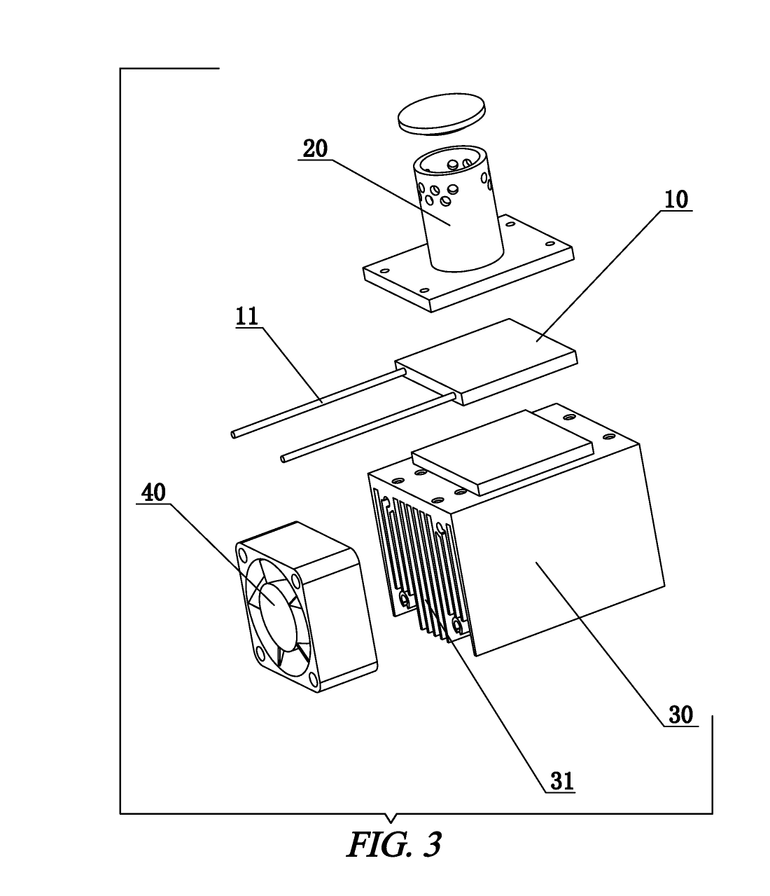

Referring to FIG. 1 to FIG. 3, illustrating a waste heat power generation device comprising a temperature difference power generation chip 10, a heat conduction block 20 is tightly attached to the hot end of the temperature difference power generation chip 10 and a radiator 30 is tightly attached to the cold end of the temperature difference power generation chip 10. The heat conduction block 20 is used for absorbing external heat and transferring the external heat to the hot end of the temperature difference power generation chip 10, the radiator 30 is used for absorbing and radiating the heat at the cold end of the temperature difference power generation chip 10, and thus a temperature difference is generated between the cold end and hot end of the temperature difference power generation chip 10, so that current is generated by the temperature difference power generation chip 10 and transferred to the exterior for storage and use via a current output end 111 of the temperature difference power generation chip 10. According to the invention, the external waste heat can be absorbed by the heat conduction block 20 and converted into electrical energy by the temperature difference power generation chip 10 for use. With the radiator 30 arranged at the cold end of the temperature difference power generation chip 10, the temperature difference between the cold end and hot end of the temperature difference power generation chip 10 is increased, thus the power generation efficiency is improved, and the waste heat power generation device is energy-saving and environment-friendly.

The radiator 30 can be of a conventional fin-type radiator structure, and can also be of a heat dissipating water tank structure or a combination thereof. When a heat dissipating water tank structure is adopted, a water inlet 32 and a water outlet can be provided therein, and thus the heat dissipating water tank can be connected with an external water source to form a water-cooling circulation loop, and the radiating efficiency is improved. A radiating fan 40 can further be arranged on the side of the radiator 30 so as to strengthen the airflow around the radiator 30 and further improve the radiating efficiency, and thus the power generation efficiency is improved.

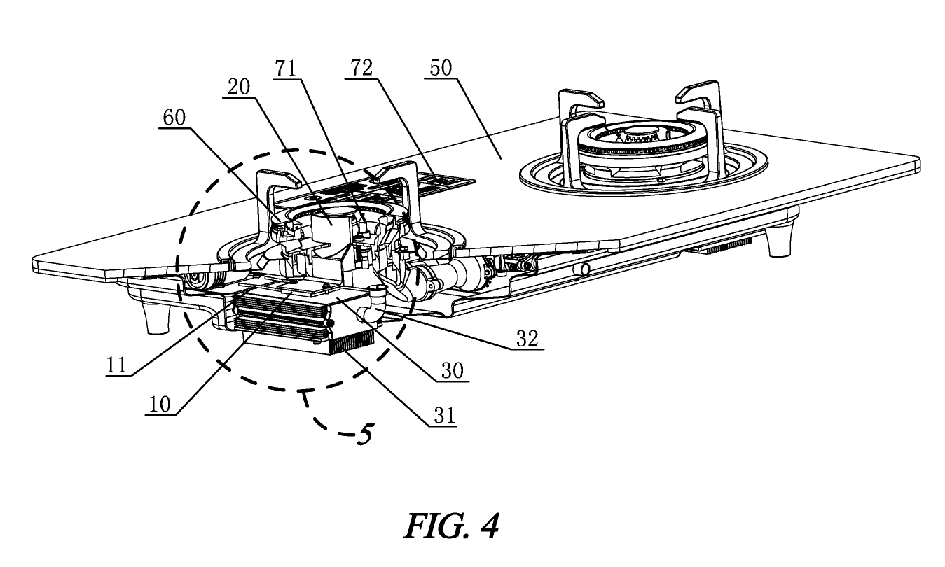

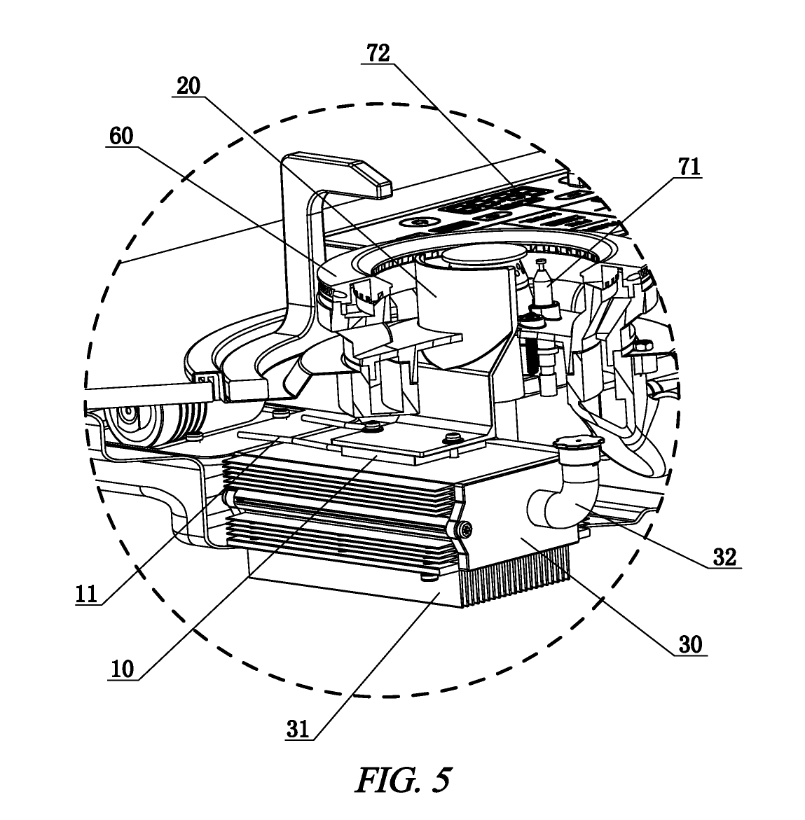

Referring to FIG. 4 and FIG. 5, in the first embodiment of a gas appliance of the present invention, the gas appliance is a gas cooking appliance, which comprises a shell 50 provided with a combustor therein, at least one electrical device, a chargeable battery for supplying power for the electrical device and a waste heat power generation device. The heat conduction block 20 of the waste heat power generation device extends to the flames generated when the combustor 60 works, and may directly absorb the heat generated from the combustor 60. The bottom of the heat conduction block 20 is tightly attached to the hot end of the temperature difference power generation chip 10, and its cold end is tightly attached to a heat dissipating water tank. A water inlet 32 is provided in the heat dissipating water tank, and a plurality of radiating fins 31 are also arranged on the outer wall of the heat dissipating water tank, wherein the radiating fins 31 positioned at the bottom of the heat dissipating water tank pass through an opening at the bottom of the shell 50 and extends to the outside of the shell 50. The current output end 11 of the temperature difference power generation chip 10 is electrically connected with the battery. In the present invention, the heat generated when the combustor 60 works can be directly absorbed by the heat conduction block 20, thus the temperature of the hot end of the temperature difference power generation chip 10 can be effectively improved; moreover, much more heat can be absorbed by the heat dissipating water tank, and radiated to the outside through the radiating fins 31, so that the temperature of the cold end of the temperature difference power generation chip 10 can be effectively reduced, the temperature difference between the cold end and hot end of the temperature difference power generation chip 10 is increased, and the power generation efficiency is improved. Since the temperature inside the shell 50 of the gas cooking appliance is usually very high, a part of radiating fins 31 are arranged outside the shell 50 on as to facilitate radiating heat in the embodiment. The water inlet 32 is provided in the heat dissipating water tank, so that cooling liquid in the heat dissipating water tank can be conveniently replaced when the gas cooking appliance is continuously used for a long period of time, and the radiating efficiency of the heat dissipating water tank is guaranteed. A water outlet can also be provided, and thus the heat dissipating water tank is communicated with an external cold water source to form a water-cooling circulation loop to further improve the radiating efficiency.

In the embodiment, the electrical device comprises a conventional electronic ignition device 71 and an electronic control device 72, and other conventional electrical devices such as an electronic alarm device and a temperature detection device can also be provided as needed.

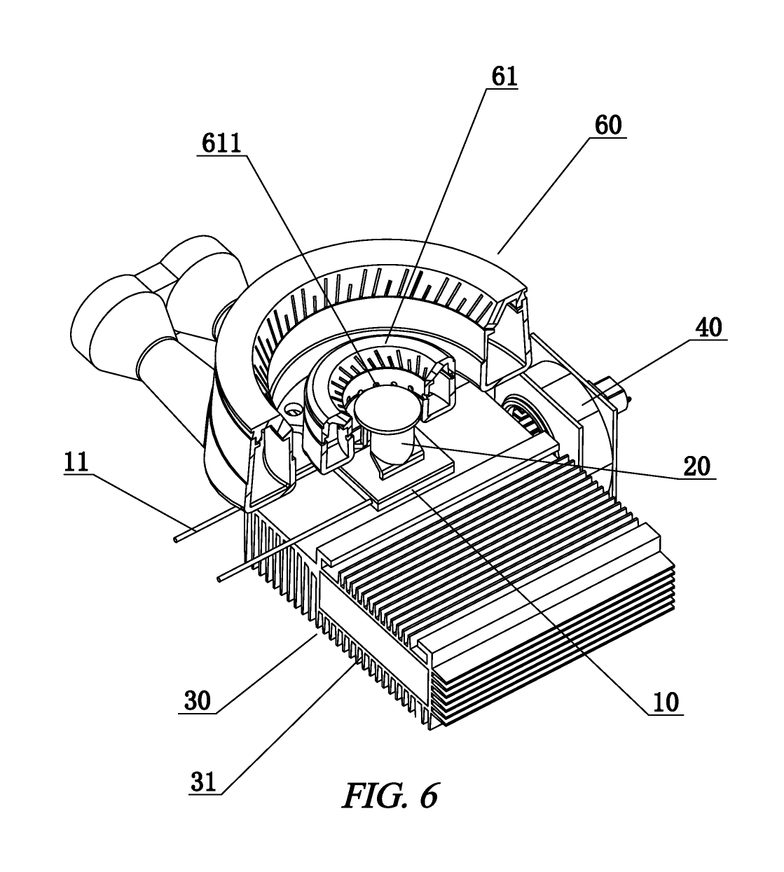

Referring to FIG. 6, in the second embodiment of the gas appliance of the present invention, the gas appliance is similarly a gas cooking appliance. It differs from the gas appliance of the first embodiment in that the combustor 60 comprises a hollow cylinder-shaped annular nozzle 61, the heat conduction block 20 extends into the inner cavity of the annular nozzle 61, and a plurality of side gas spray ports 611 aligning to the heat conduction block 20 are formed in the inner wall of the annular nozzle 61. Moreover, a radiating fan 40 is arranged at the side of the radiator 30, and airflow generated when the radiating fan 40 works flows through gaps between adjacent radiating fins 31. In the embodiment, the side gas spray ports 611 capable of directly heating the heat conduction block 20 are additionally provided in the inner wall of the annular nozzle 61, so that the heat conduction block 20 can be hidden in the inner cavity of the annular nozzle 61 and does not shield flames for heating the cooker, and thus the cooking and heating effects of the combustor 60 will not be influenced, and the cooking appliance is thereby attractive in appearance. The semi-closed inner cavity structure of the annular nozzle 61 can obviously increase the air temperature inside the inner cavity, and thus the temperature of the hot end of the temperature difference power generation chip 10 can be obviously increased. The radiating fan 40 can strengthen the airflow in the gaps between the adjacent radiating fins 31, and the radiating efficiency is effectively improved, so that the temperature difference between the cold end and hot end of the temperature difference power generation chip 10 can be obviously increased, and the power generation efficiency is improved.

The heat conduction block 20 in the embodiment is hollow cylinder-shaped and is similar to and concentrically arranged with the annular nozzle in shape. The side gas spray ports 611 are circumferentially and uniformly provided along the inner wall of the annular nozzle, so that the heat absorption surface of the heat conduction block 20 is increased. Two openings are also provided in the sides of the heat conduction block 20, which can prevent the heat conduction block 20 from being deformed under the effect of heat expansion and cold contraction, and can also enable the flames of the side gas spray ports 611 to enter the inner cavity of the heat conduction block 20, so that the heat absorption surface of the heat conduction block 20 is further enlarged, the heat absorption efficiency of the heat conduction block 20 is improved, and then the power generation efficiency is improved.

Moreover, the gas appliance in the present invention can also be conventional gas equipment such as a gas warmer, a baking oven, a baking stove and a gas water heater.

When the gas appliance is a gas warmer, the airflow inside the combustor of the gas warmer can be promoted by utilizing the radiating fan 40, hot air is promoted to flow out from a warming window of the combustion chamber, and the warming effect of the gas warmer is promoted. When the gas appliance is a gas water heater, the radiator 30 can be selectively the heat dissipating water tank, and the heat dissipating water tank is serially connected into a cold water inlet pipeline of the gas water heater, so that the heat dissipating water tank can transmit the absorbed heat to a heat exchanger of the gas water heater when the cold end of the temperature difference power generation chip 10 is cooled, and the waste heat power generation device is energy-saving and environment-friendly.

The above mentioned examples are merely preferable embodiments of the present invention, any technical solutions for realizing the purpose of the present invention by basically the same means belongs to the scope of protection in the present invention.

What is claimed is:

1. A waste heat power generation device comprising:
a temperature difference power generation chip,
a heat conduction block tightly attached to the hot end of the temperature difference power generation chip, and
a radiator tightly attached to the cold end of the temperature difference power generation chip,
wherein the heat conduction block is used for absorbing external heat and transferring the external heat to the hot end of the temperature difference power generation chip, and a current output end is arranged on the temperature difference power generation chip.

2. The waste heat power generation device of claim 1, wherein the radiator is a heat dissipating water tank.

3. The waste heat power generation device of claim 2, wherein a water inlet and a water outlet are provided in the heat dissipating water tank.

4. The waste heat power generation device of claim 1, wherein a plurality of radiating fins are arranged on the outer wall of the radiator.

5. The waste heat power generation device of claim 4, wherein a radiating fan is also arranged on the side of the radiator, and airflow generated when the radiating fan works flows through gaps between adjacent radiating fins.

6. A gas appliance, comprising:
a combustor,
at least one electrical device,
a chargeable battery for supplying power for the electrical device, and
at least one waste heat power generation device of claim 1,
wherein the current output end of the temperature difference power generation chip is electrically connected with the battery, and the heat conduction block is used for absorbing and transmitting heat generated when the combustor works.

7. The gas appliance of claim 6, wherein the heat conduction block extends to the flames generated when the combustor works.

8. The gas appliance of claim 6, wherein the combustor comprises a hollow cylinder-shaped annular nozzle, the heat conduction block extends into the inner cavity of the annular nozzle, and a plurality of side gas spray ports aligning to the heat conduction block are provided in the inner wall of the annular nozzle.

9. The gas appliance of claim 6, further comprising a shell, wherein the combustor is arranged in the shell, and the radiator is positioned outside the shell.
